(19) United States
(12) Patent Application Publication
(10) Pub. No.: US 2015/0207254 A1
(43) Pub. Date: Jul. 23, 2015

(54) Molded Plastic Structures With Graphene Signal Paths

(71) Applicant: Apple Inc., Cupertino, CA (US)

(72) Inventors: Ibuki Kamei, San Jose, CA (US); Eric S. Jol, San Jose, CA (US); Warren Z. Jones, San Jose, CA (US)

(73) Assignee: Apple Inc., Cupertino, CA (US)

(21) Appl. No.: 14/161,387

(22) Filed: Jan. 22, 2014

(51) Int. Cl. H01R 13/03; H05K 1/09; H05K 1/18; H05K 1/02

(52) U.S. Cl. CPC H01R 13/035; H05K 1/0284; H05K 1/09; H05K 1/18

(57) ABSTRACT

A connector or other structure may be provided with dielectric material and conductive traces. The dielectric material may include plastic structures such as molded plastic members. Elastomeric material may allow part of a connector to flex when the connector is mated with a corresponding connector. Printed circuits may be used to mount electrical components. Conductive traces may be formed on plastic structures such as molded plastic structures, on elastomeric members, on printed circuits, and on other structures. The conductive structures may form signal interconnects, ground plane structures, contacts, and other signal paths. The conductive traces may be formed from metal and other conductive materials such as graphene. Graphene may be deposited using inkjet printing techniques or other techniques. During inkjet printing, graphene may be patterned to form signal lines, connector contacts, ground planes, and other structures.

### BACKGROUND

This relates generally to structures for electronic devices such as input-output connectors and, more particularly, to structures with graphene signal paths.

Electronic devices often include input-output connectors and other structures that are formed from molded plastic parts. It can be challenging to route signals within these molded plastic parts. Some connectors form signal paths using stamped sheet metal. Stamped sheet metal structures may, however, be bulky. Metal can be deposited using physical vapor deposition techniques, but metal coatings that are formed in this way may not be conformal and may be overly thick.

It would therefore be desirable to be able to form improved structures for electronic devices such as molded plastic structures for input-output connectors or other device structures.

### SUMMARY

A connector or other structure may be provided with dielectric material and conductive traces. The dielectric material may include plastic structures such as molded plastic members. Elastomeric material may allow part of a connector to flex when the connector is mated with a corresponding connector.

Printed circuits may be used to mount electrical components. Conductive traces may be formed on printed circuits, on plastic connector structures such as molded plastic structures, on elastomeric members in a connector, or on other dielectric structures. The conductive structures may form signal interconnects, ground plane structures, contacts, and other conductive paths.

The conductive traces may be formed from metal and other conductive materials such as graphene. Graphene traces may be deposited using inkjet printing techniques or other deposition and patterning techniques. During inkjet printing, graphene may be patterned to form signal lines on a connector structure, printed circuit, or other structure, contacts on a printed circuit board or other structure, connector contacts on a connector structure, ground structures on a connector, printed circuit, or other structure, or other conductive structures.

### BRIEF DESCRIPTION OF THE DRAWINGS

FIG. 1 is a diagram of an illustrative electronic device of the type that may be provided with structures having a printed graphene signal paths in accordance with an embodiment.

FIG. 2 is a perspective view of an illustrative structure onto which a graphene signal path is being printed using inkjet printing equipment in accordance with an embodiment.

FIG. 3 is a cross-sectional side view of an illustrative structure onto which a graphene signal path is being printed in accordance with an embodiment.

FIG. 4 is a cross-sectional side view of a structure with steps that have been provided with a minimum radius of curvature to accommodate printed graphene signal paths in accordance with an embodiment.

FIG. 5 is a system diagram showing equipment of the type that may be used in forming structures including printed graphene signal paths in accordance with an embodiment.

FIG. 6 is a cross-sectional side view of a structure with a printed graphene signal path and a metal pad that has been attached to the printed graphene signal path with a conductive material in accordance with an embodiment.

FIG. 7 is a cross-sectional side view of a structure with a printed graphene signal path and a metal pad that has been deposited directly on the printed graphene signal path in accordance with an embodiment.

FIG. 8 is a cross-sectional side view of an illustrative pair of mating structures such as connector structures of the type that may include one or more printed graphene signal paths in accordance with an embodiment.

FIG. 9 is a cross-sectional side view of the mating structures of FIG. 8 after the structures have been joined together to short a conductive path on one structure to a corresponding conductive path on the other structure in accordance with an embodiment.

FIG. 10 is a cross-sectional side view of an illustrative pair of mating connectors of the type that may be provided with printed graphene signal paths such as signal paths that extend from a rigid tongue across an elastomeric member in accordance with an embodiment.

FIG. 11 is a perspective view of an illustrative connector of the type that may have a plastic tongue or other dielectric structure with printed graphene signal paths in accordance with an embodiment.

FIG. 12 is a cross-sectional side view of an illustrative connector with printed graphene signal paths in accordance with an embodiment.

FIG. 13 is a perspective view of an illustrative connector tongue member having printed graphene signal paths including ground traces that are wrapped around multiple sides of the tongue member in accordance with an embodiment.

FIG. 14 is a cross-sectional view of a portion of the tongue structure of FIG. 13 in accordance with an embodiment.

FIG. 15 is a perspective view of an illustrative connector structure with printed graphene traces in accordance with an embodiment.

FIG. 16 is a cross-sectional side view of a printed circuit board and an overmolded plastic structure with printed graphene paths in accordance with an embodiment.

FIG. 17 is a cross-sectional side view of a printed circuit board with an embedded component such as an integrated circuit that is connected to printed graphene paths in accordance with an embodiment.

### DETAILED DESCRIPTION

Electronic device structures such as molded plastic parts for input-output connectors and other structures may be provided with conductive signal paths. The signal paths may be formed form an inkjet-printed conductive material, conductive material that is deposited using other printing techniques (e.g., screen printing, pad printing, etc.), or conductive material that is deposited and patterned using other fabrication methods.

Printed conductive material may be, for example, graphene that is deposited using inkjet printing. Graphene is highly conductive and can be printed in thin layers using inkjet printing techniques Inkjet-printed graphene traces may form conformal signal paths that accommodate a variety of planar and non-planar surface topologies. Graphene signal paths may include ground plane structures, shielding structures, signal lines for analog and/or digital data signals, power paths, contacts, or other conductive paths. Solder connections, connections formed from conductive adhesive, and other connections may be formed to interconnect patterned graphene to metal paths and other conductive paths.

Printed graphene paths may be formed on plastic structures in an input-output connector associated with a cable or other accessory, on plastic structures or other dielectric structures in an input-output connector in an electronic device, or on other structures that are formed within an electronic device or that operate in conjunction with an electronic device. For example, printed graphene traces or other graphene paths may be formed on a connector that is formed as part of an electronic device or may be formed on a connector that is attached to a cable that is plugged into a port on an electronic device.

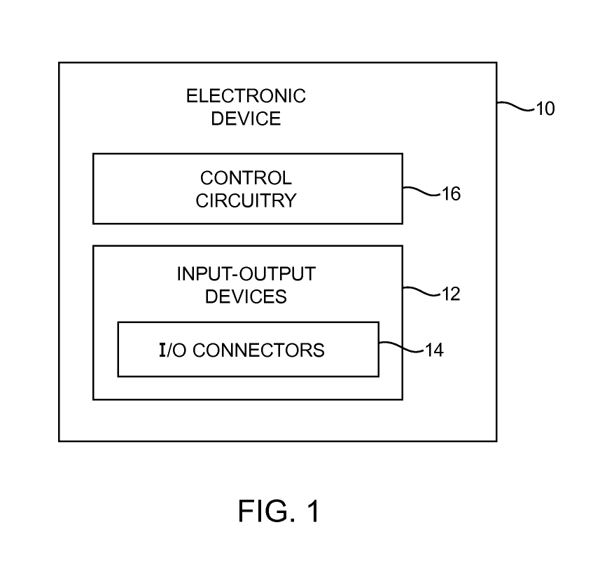

An illustrative electronic device of the type that may incorporate structures with printed graphene traces or that may operate in conjunction with a cable or accessory having an input-output connector with printed graphene traces is shown in FIG. 1. As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio codec chips, application specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, click wheels, scrolling wheels, touch pads, key pads, keyboards, microphones, speakers, tone generators, vibrators, cameras, sensors, light-emitting diodes and other status indicators, data ports, displays, etc. A user can control the operation of device 10 by supplying commands through input-output devices 12 and may receive status information and other output from device 10 using the output resources of input-output devices 12.

Input-output devices 12 may include one or more input-output connectors such as input-output connectors 14. Connectors 14 may be digital data connectors, analog signal connectors, connectors that handle power, analog signals, and/or digital data, or other input-output connectors. Connectors such as these may have printed graphene traces and may, if desired, be formed as part of an accessory, cable, or other external device component.

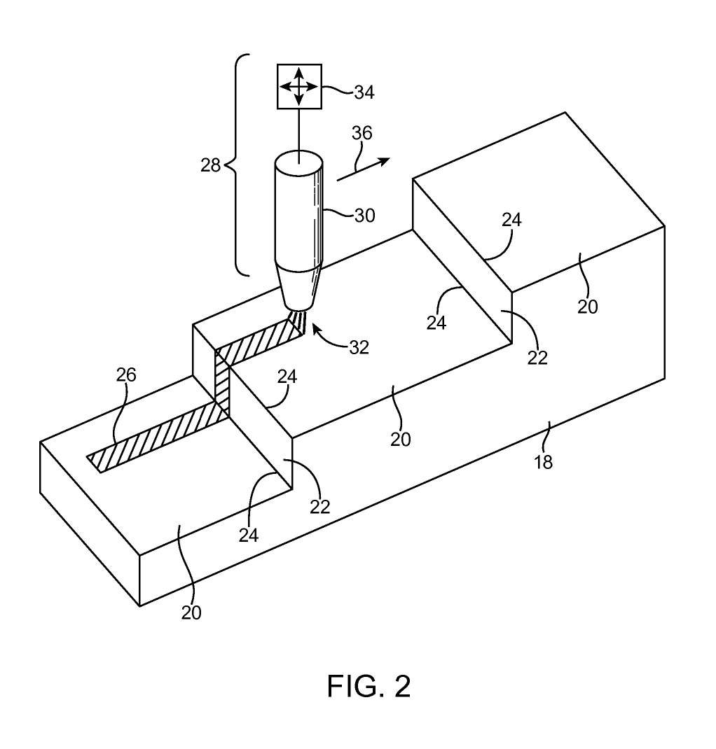

FIG. 2 is a perspective view of an illustrative structure on which a printed graphene trace is being formed. As shown in FIG. 2, structure 18 may include horizontal surfaces 20 and vertical surfaces 22 that are joined by right-angle bends 24 Inkjet-printed graphene trace 26 may overlap bends 24. Structure 18 may be formed from polymer, glass, ceramic, metal, carbon-fiber composite material or other fiber composite material, other dielectrics, other materials, or combinations of these materials. As an example, structure 18 may be formed from molded plastic, machined plastic, thermoset polymer material, or thermoplastic polymer material. If desired, structure 18 may include a metal base structure or a support structure that is formed from other conductive material and an insulating coating formed from an organic material (e.g., polymer) or inorganic material.

Graphene paths such as graphene trace 26 may be formed on the surface of structure 18. For example, inkjet printing equipment 28 or other suitable graphene deposition equipment may be used in depositing graphene onto the surface of structure 18 Inkjet printing equipment may include one or more printing heads such as printing head 30 that dispense graphene in liquid form (see, e.g., graphene 32 that is being dispensed from the tip of printing head 30). Printing head 30 may contain one or more inkjet nozzles. Once deposited onto structure 18, the liquid material in which the graphene is deposited may be evaporated (at room temperature or at an elevated temperature), leaving graphene traces such as graphene trace 26 on structure 18.

Graphene inkjet printing equipment 28 may have a manually controlled positioner and/or computer controlled positioner for adjusting the position of inkjet printing head 30. For example, graphene inkjet printing equipment 28 may have a positioner such as positioner 34 that helps move printing head 30 in direction 36 along the surface of structure 18 during graphene inkjet printing operations.

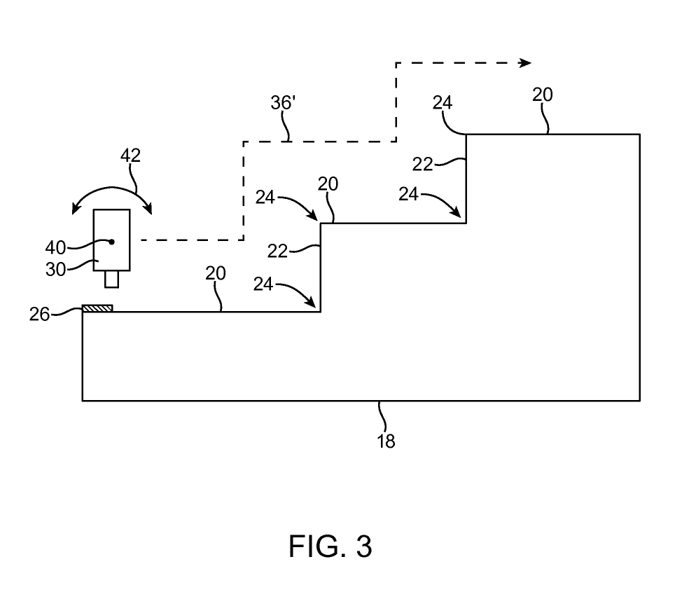

If desired, the orientation of printing head 30 relative to structure 18 may be adjusted in real time using positioner 34. As shown in FIG. 3, for example, printing head 30 may be moved along a path such as path 36′ that runs parallel to the surface of structure 18 onto which graphene trace 26 is being printed. In this way, the height of printing head 30 above the surface of structure 18 may remain constant to help ensure uniform trace deposition. If desired, the angular orientation of printing head 30 may be adjusted to help ensure that graphene traces are deposited as desired, particularly when traversing abrupt changes in surface orientation such as bends 24. For example, printing head 30 may be rotated in directions 42 about rotational axis 40 by positioner 34 (FIG. 2) as printing head 30 is being moved along a path such as path 36′ to help ensure that graphene is being deposited onto the surface of structure 18 at a desired angle even in the presence of right-angle bends 24 between horizontal surfaces 20 and vertical surfaces 22. For example, printing head 30 may be rotated to maintain head 30 at a 90° angle or other suitable angle with respect to the adjacent surface of structure 18.

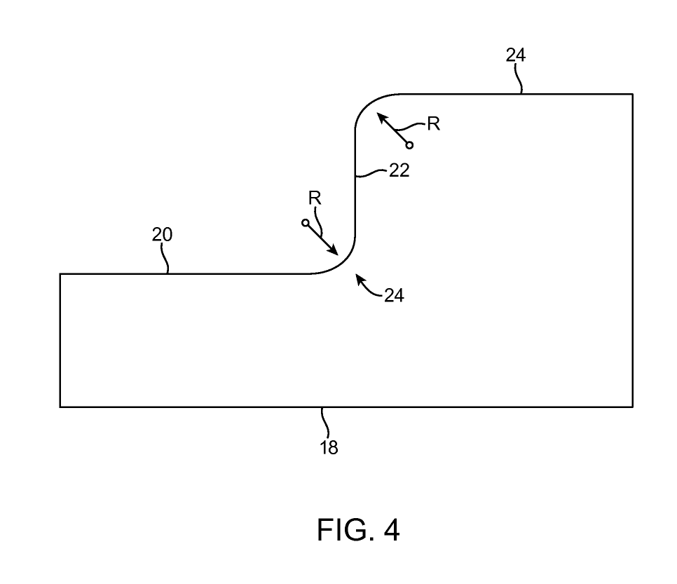

FIG. 4 is a cross-sectional side view of an illustrative structure 18 of the type that may receive inkjet-printed graphene traces 26. As shown in FIG. 4, it may be desirable to provide right-angle bends such as bends 24 with a minimum radius of curvature R. The value of R may be, for example, 0.01 mm, a value in the range of 0.01-1 mm, a value in the range of 0.05-0.1 m, 0.1 or more than 0.1 mm, 0.2 or more than 0.2 mm, 0.3 or less than 0.3 mm, 0.15 or less than 0.15 mm, 0.05 or less than 0.05 mm, or other suitable bend radius value or minimum radius of curvature value. By ensuring that the surface of structure 18 changes orientation gradually in the vicinity of bends 24 (i.e., by ensuring that the radius of curvature of structure 18 at each right-angle bend or other bend exceeds a desired minimum radius of curvature), undesired over-thinning of printed graphene traces 26 at bends 24 may be avoided.

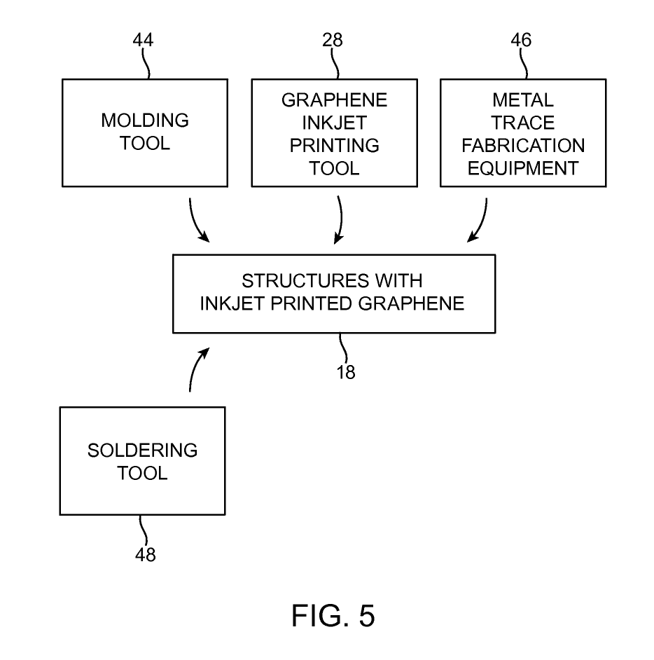

Illustrative equipment for forming structures with printed graphene traces is shown in FIG. 5. As shown in FIG. 5, equipment such as molding tool 44, graphene inkjet printing tool 28 (or other graphene trace deposition equipment such as spraying equipment, pad printing equipment, etc.), metal trace fabrication equipment 46, and conductive joint formation equipment such as soldering tool 48 may be used in forming structure 18 with inkjet-printed graphene traces 26.

Molding tool 44 may be used in forming structure 18 from a thermoplastic resin or thermoset resin. For example, molding tool 44 may be a plastic injection molding tool with a heated die for forming molded plastic parts from a thermoplastic material. Molding tool 44 may, if desired, mold plastic over other structures (e.g., printed circuit boards, metal parts, other plastic parts such as elastomeric parts, etc.).

Graphene inject printing tool 28 may have a computer-controlled positioner such as positioner 34 of FIG. 2 and one or more inkjet printing heads such as inkjet printing head 30 for inkjet printing patterned graphene onto the surface of structure 18. If desired, structure 18 may incorporate metal traces.

Metal traces on structure 18 may be formed using metal trace fabrication equipment 46 such as metal deposition equipment, metal patterning equipment (e.g., lithographic tools, etching equipment, etc.), and other equipment for forming a metal coating on structure 18 with a desired pattern.

Metal traces and/or graphene traces 26 on structures such as structure 18 may be interconnected using conductive joints (e.g., welds, solder, conductive adhesive, etc.). As shown in FIG. 5, equipment such as soldering tool 48 may be used in forming conductive joints between metal traces and graphene traces on structure 18.

Graphene traces 26 (e.g., graphene traces patterned to form one or more connector contacts on a dielectric structure such as a plastic structure) may be covered with a layer of metal or other material to help enhance the durability of a connector contact. For example, in an input-output connector or other device in which connector contacts rub against mating contacts (e.g., mating connector contacts in a corresponding input-output connector on another device or accessory), a layer of metal may be formed on top of a layer of graphene.

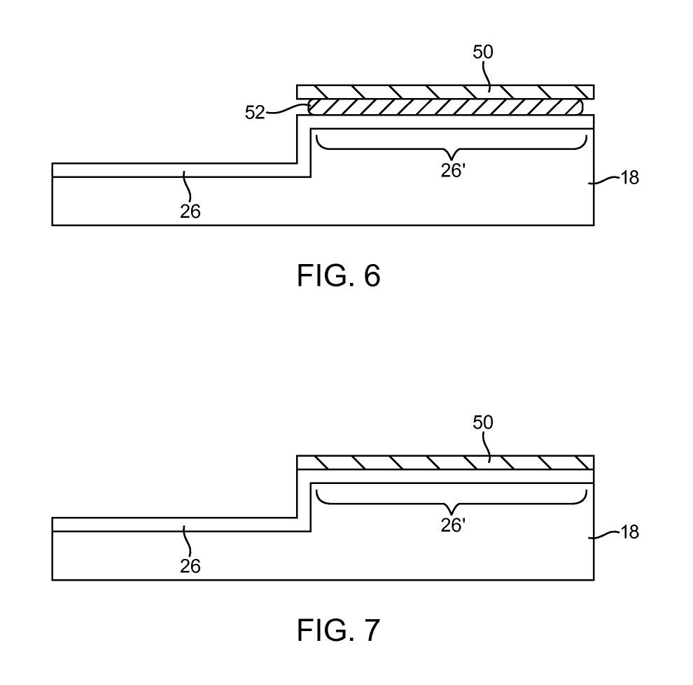

As shown in the illustrative side view of structures 18 in FIG. 6, for example, graphene trace 26 may be covered with a metal pad such as pad 50. Pad 50 may be formed from a thin sheet of metal (e.g., a sheet of gold, aluminum, or other metal). Metal pad 50 may be coupled to graphene trace 26 on structure 18 using conductive material 52. Conductive material 52 may be conductive adhesive or other conductive material. As an example, conductive material 52 may be solder. Soldering tool 48 of FIG. 5 may be used in soldering pad 50 to portion 26′ of graphene trace 26 to help enhance the robustness of portion 26′ (e.g., so that portion 26′ may serve as a wear-resistant contact in an input-output connector).

As shown in the illustrative configuration of FIG. 7, metal pad 50 may, if desired, be a metal trace that is deposited directly on top of graphene trace 26 in region 26′. Equipment 46 may, for example, include physical vapor deposition equipment and a shadow mask for forming a layer of metal for pad 50, may include photolithographic equipment, or may include patterned metal ink printing equipment (e.g., an inkjet printer, spray coating equipment, pad printing equipment, screen printing equipment, etc.).

If desired, multiple metal layers may be formed on top of a region of graphene such as graphene region 26′ of FIGS. 6 and 7. These additional layers may be formed directly on lower layers and/or may be attached using intervening layers of conductive material such as conductive adhesive, solder 52, etc.

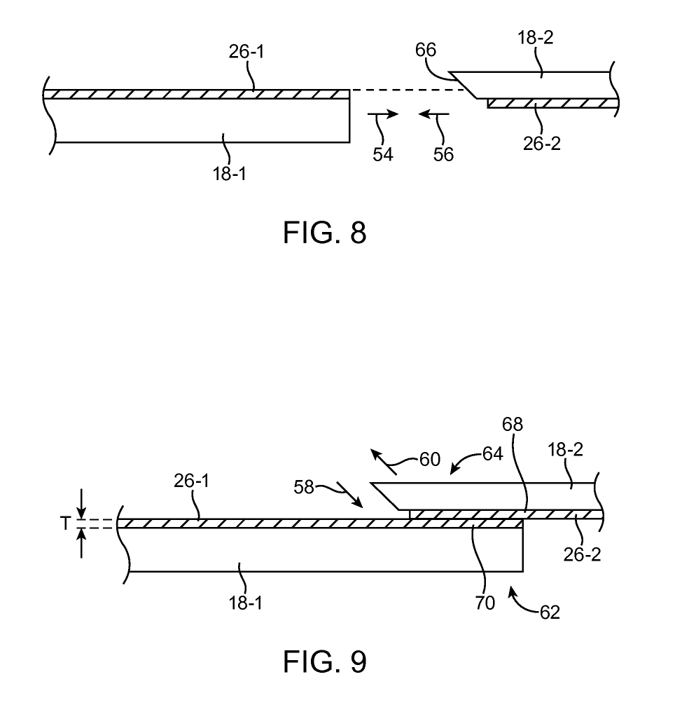

FIG. 8 is a cross-sectional side view of a pair of illustrative structures such as connector structures for connectors 14 of FIG. 1. As shown in FIG. 8, connector parts or other structures may be provided with mating conductive layers such as conductive layers 26-1 and 26-2. Conductive layers 26-1 and 26-2 may be respectively formed on connector structures 18-1 and 18-2 or other connector members. Conductive layers 26-1 and 26-2 may be layers of metal and/or inkjet-printed graphene traces or other conductors. Connector structure 18-1 may have upper conductive layer 26-1 (e.g., a metal trace and/or a graphene trace). Connector structure 18-2 may have lower conductive layer 26-2 (e.g., a metal trace and/or a graphene trace). If desired, connector structures 18-1 and 18-2 may have other conductive layers. For example, structure 18-1 may have a lower conductive trace and structure 18-2 may have an upper conductive trace.

Structures 18-1 and/or 18-2 may be formed from dielectric such as rigid plastic and/or flexible plastic (e.g., elastomeric material). Structures 18-1 and 18-2 may be associated with respective input-output connectors. For example, structure 18-1 may be a plastic member associated with a plug and structure 18-2 may be a plastic member associated with a matching receptacle for the plug. As shown in FIG. 8, one or both of members 18-1 and 18-2 may have an angled surface such as surface 66. When members 18-1 and 18-2 are moved towards each other in respective directions 54 and 56, angled surface 66 may strike an opposing tip portion of member 18-1, thereby causing member 18-2 to move upwards in direction 60 and/or causing member 18-2 to move downwards in direction 58, as shown in FIG. 9. In this way, portion 64 of conductive trace 26-2 and mating portion 70 of conductive trace 26-1 may rub against each other and thereby form a low resistance electrical contact between trace 26-1 and 26-2.

Particularly when traces such as traces 26-1 and/or 26-2 are formed from inkjet-printed graphene, these traces may exhibit relatively small values of thickness T. For example, thickness T may be about 0.15-0.2 mm when a trace is formed from a metal such as copper, but may be about ten times thinner (e.g., 0.015-0.02 mm) when formed from graphene. As an example, traces 26-1 and/or 26-2 may be formed form inkjet-printed graphene having a thickness of less than 0.3 mm, less than 0.2 mm, less than 0.1 mm, less than 0.05 mm, less than 0.02 mm, less than 0.01 mm, 0.001-0.05 mm, 0.001-0.03 mm, 0.001-0.02 mm, or other suitable thicknesses. If desired, printed graphene traces 26-1 and/or 26-2 may be covered with metal pads such as pads 50 of FIGS. 6 and 7 (e.g., pads attached to traces 26-1 and/or 26-2 using solder 52 or direct deposition techniques).

As shown in FIG. 9, as members 18-1 and 18-2 are moved towards each other, portion 68 of trace 26-2 wipes across the surface of portion 70 of trace 26-1, thereby forming a low contact resistance electrical connection between trace 26-1 and 26-2. This type of connection may be formed for one or more leads in each connector. For example, a plug and a mating plug receptacle may each have one contact, two contacts, 2-10 contacts, more than 5 contacts, more than 10 contacts, 3-50 contacts, less than 25 contacts, or other suitable number of contacts formed from metal traces and/or graphene traces such as inkjet-printed graphene traces. In addition to portions 68 and 70, which contact each other when the connector structures are mated as shown in FIG. 9, traces such as traces 26-1 and 26-2 may be patterned to form signal paths that couple portions 70 and 68 to other signal lines in a connector, electronic device, or other equipment.

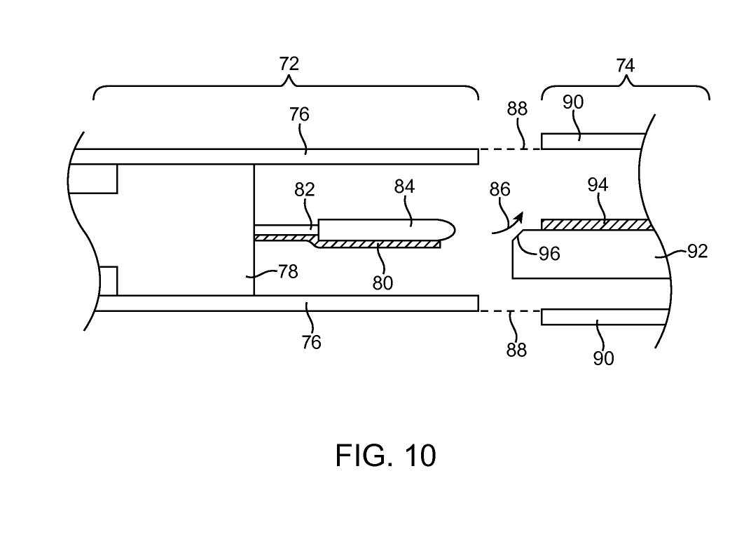

FIG. 10 is a cross-sectional side view of a pair of illustrative connectors with conductive paths of the type that may be formed using graphene traces such as inkjet-printed graphene traces. Connector 72 has metal outer shell 76. Dielectric support structure 78 may be formed from a molded plastic member or other dielectric structure and may be mounted within the interior of metal shell 76. Elastomeric member 82 may be coupled between tongue member 84 and support member 78. Tongue member 84 may be formed from a rigid dielectric such as molded plastic. Elastomeric member 82 may be formed from flexible plastic. The thickness of member 82 may also be configured to be less than the thickness of member 84 to help ensure that member 82 is more flexible than member 84.

Inkjet-printed graphene traces such as trace 80 may be formed on connector structures such as tongue member 84 and elastomeric member 82. The presence of elastomeric member 82 may allow tongue 84 to ride up and over angled leading surface 96 of mating connector member 92 in direction 86 when connector 72 is plugged into connector 74. Connector 74 may have a shell such as metal shell 90. If desired, structures such shell 76 and shell 90 may be grounded. A support structure such as a molded plastic support member may be used to support connector tongue member 92. Tongue member 92 may have conductive signal paths formed from conductive traces such as trace 94. Trace 94 may be formed from metal or inkjet-printed graphene. When connectors 72 and 74 are coupled together, trace 80 will form an electrical connection with trace 94. Elastomeric member 82 will allow tongue member 84 to flex upwards and will help to bias connector contacts formed from traces such as trace 80 in connector 72 towards mating contacts formed from traces such as trace 94 in connector 74.

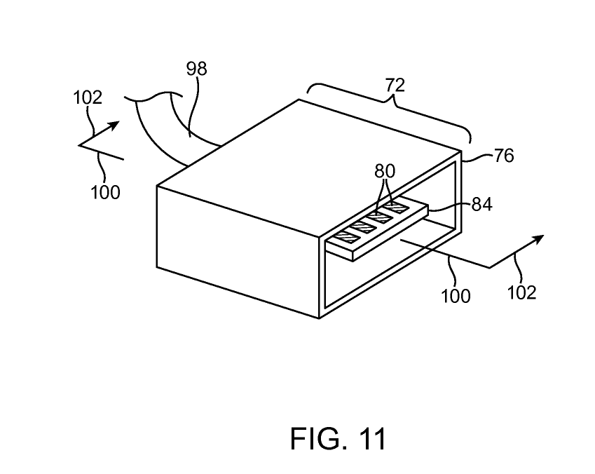

A perspective view of an illustrative connector with printed graphene traces such as connector 72 of FIG. 10 is shown in FIG. 11. As shown in FIG. 11, connector 72 may be coupled to a signal cable such as cable 98. Cable 98 may contain a bundle of metal wires surrounded by an insulating plastic jacket. Each metal wire in cable 98 may be connected to a respective printed graphene trace 80 in connector 72 (as an example) Inkjet-printed graphene traces 80 may be formed on the upper and/or lower surfaces of plastic connector tongue 84. Tongue 84 may be mounted within connector shell 76.

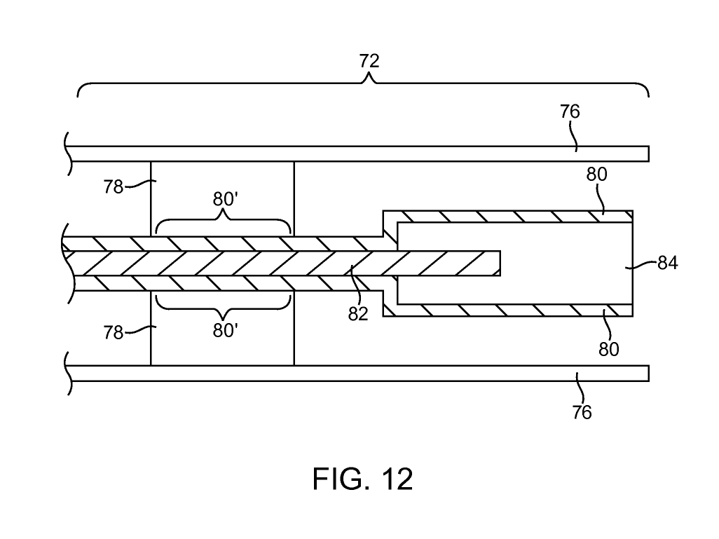

FIG. 12 is a cross-sectional side view of an illustrative connector such as connector 72 of FIG. 11 taken along line 100 and viewed in direction 102 of FIG. 11. As shown in FIG. 12, support structure 78 may be mounted in metal shell 76. Printed graphene traces 80 may be formed on opposing upper and lower surfaces of plastic tongue member 84 and elastomeric member 82. One end of member 82 (i.e., the innermost end) may be supported by support structure 78. The other end of member 82 (i.e., the opposing outermost end) may be used to support tongue member 84. Printed graphene traces 80 may be used to form connector contacts on tongue member 84. Portions of graphene traces 80 may form signal lines that travel from tongue 80, along elastomeric member 82 to metal wires in cable 98 (see, e.g., trace portions 80′ that pass through support structure 78). With an arrangement of the type shown in FIG. 12, signals can be conveyed along both the upper surface and the opposing lower surface of tongue member 76.

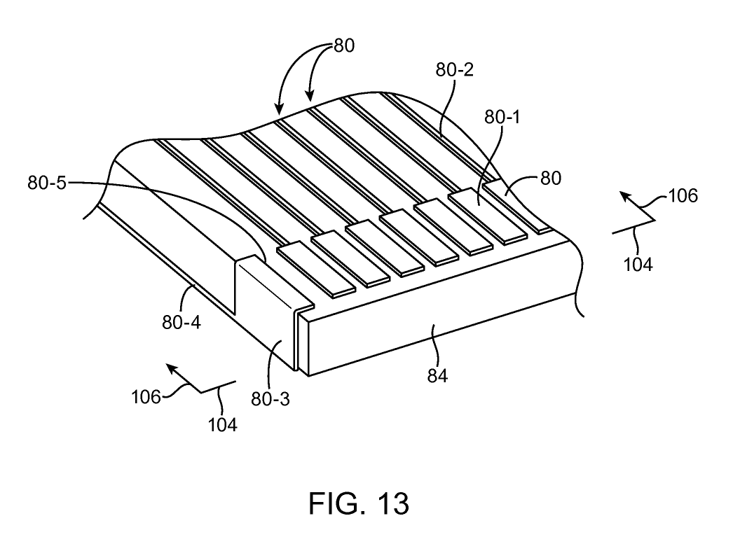

FIG. 13 is a perspective view of a tip portion of tongue member 84 in an illustrative connector configuration having printed graphene traces 80 that form signal contacts and a ground conductor (i.e., a ground contact, ground shielding structure, or other ground). As shown in FIG. 13, inkjet-printed graphene traces 80 may have enlarged portions that form connector contacts 80-1. Contacts 80-1 may each be connected to a respective signal line 80-2 that is formed from a portion of a respective inkjet-printed graphene trace 80. Some portions of inkjet-printed graphene traces 80 may extend along the left and/or right sides and upper and/or lower sides of member 84. For example, a ground conductor may include side portions of traces 80 such as vertical side portion 80-3 and rear (lower) surface portions such as rear surface portions 80-4. Side portions 80-3 may be coupled to upper surface portions such as upper surface portion 80-5 (i.e., portions 80-5, 80-3, and 80-4 may form a graphene trace that wraps around three different sides of member 84—top, left, and bottom). Portions of traces such as ground traces may also wrap around the right side of member 84.

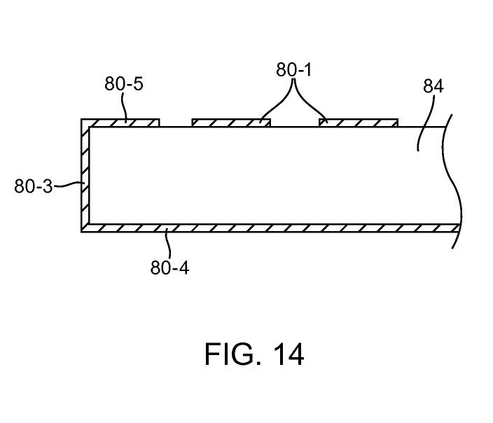

FIG. 14 is a cross-sectional view of the connector tongue structures of FIG. 13 taken along line 104 of FIG. 13 and viewed in direction 106 of FIG. 13. As shown in FIG. 14, printed graphene traces may wrap around the sides of member 84. For example, graphene may be printed onto member 84 to form a contiguous trace (e.g., a ground trace) incorporating upper portion 80-5, side 80-3, and rear portion 80-4. Rear portion 80-4 may, if desired, form a ground plane that extends under the lower surface of tongue 84.

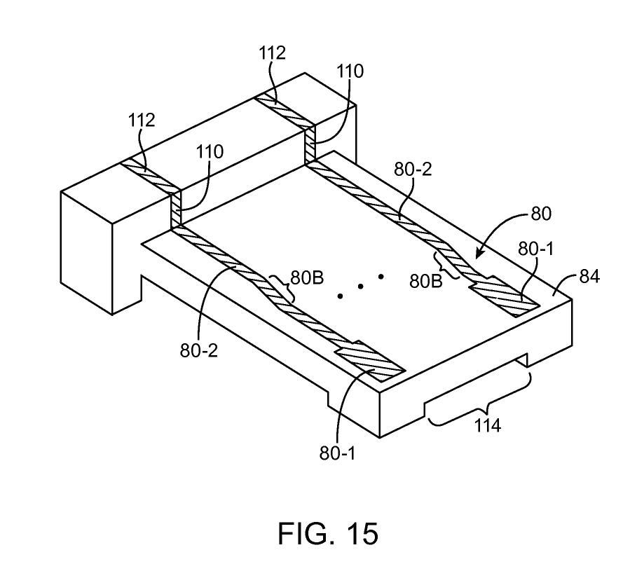

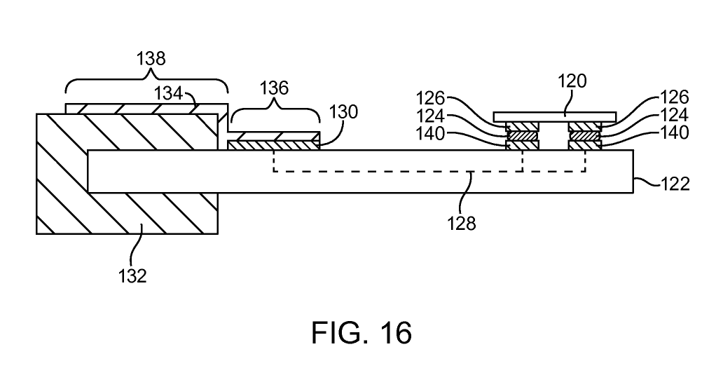

FIG. 15 is a perspective view of an illustrative connector having multiple parallel inkjet-printed traces 80. Each trace may have a contact portion 80-1, a signal line portion 80-2, and additional portions 110 and 112, that route the trace towards the rear of connector tongue 84 (e.g., to connect to a wire in a cable or other conductive structures). Traces 80 may have laterally bent portions such as bent portions 80B of signal line portions 80-2. Tongue member 84 may have surface features such as recess 114 to facilitate proper engagement with a mating connector. Portions 110 and 112 may be separated by a right-angle bend or other bend. Traces 80 may overlap the bend.

If desired, plastic and other dielectrics may be attached to printed circuits. The printed circuits may be used for mounting and interconnecting electrical components in device 10 (e.g., control circuitry, input-output devices, etc.). Graphene traces and/or metal traces may be interconnecting the electrical components.

A cross-sectional side view of an illustrative printed circuit and associated structures is shown in FIG. 16. As shown in FIG. 16, an electrical component such as electrical component 120 may be mounted on printed circuit 122. Electrical components such as component 120 may be formed from integrated circuits, surface mount technology (SMT) components, discrete components such as inductors, capacitors, and resistors, switches, connectors, sensors, and other electrical devices. Components such as component 120 may be mounted to printed circuits such as printed circuit 122 using solder 124. Solder 124 may be used to connect contacts 126 on component 120 to corresponding contact pads (contacts) 140 on printed circuit 122.

Printed circuit 122 may be a flexible printed circuit (i.e., a printed circuit formed from one or more laminated flexible substrate layers such as layers of polyimide or other flexible polymer), a rigid printed circuit board (e.g., a printed circuit formed from a rigid substrate material such as fiberglass-filled epoxy), a “rigid flex” printed circuit board, or other printed circuit board structures. Traces 128 on printed circuit 122 may be used to interconnect mounted components such as component 120 with each other and with external circuits. Surface pads such as contact pads 130 and contact pads 140 may be electrically connected to other conductive traces 128 in printed circuit 122. Traces 128 (e.g., embedded printed circuit traces and/or surface pads such as contacts 140 and 130) may be formed from metal or printed graphene.

Plastic structures such as illustrative plastic structure 132 may be overmolded on top of printed circuit 122 Inkjet printing techniques may then be used to print graphene traces such as printed graphene traces 134 onto the structures of FIG. 16. The printed graphene traces may include portions such as portion 136 that overlap contact pads 130 and other metal traces on printed circuit 122 and portions such as portion 138 that serve as interconnect lines to interconnect pads 130 to other circuitry (e.g., components mounted on support structure 132 or elsewhere in an electronic device).

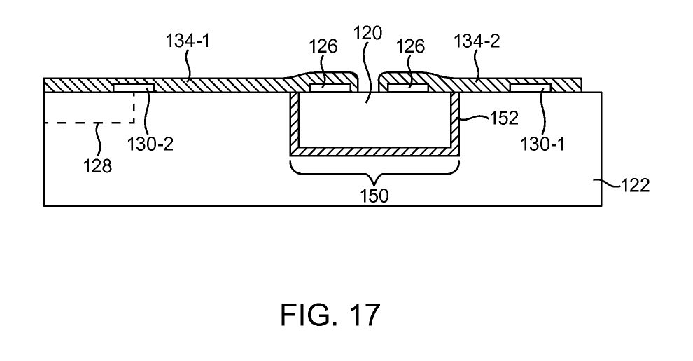

As shown in FIG. 17, printed circuit 122 may have a recessed portion such as recess 150. Recess 150 may be, for example, a rectangular hole in the surface of printed circuit board 122 that has four vertical recess sidewall surfaces and a lower surface. Components such as component 120 may be mounted within recesses such as recess 150 (e.g., so that the surface of component 120 protrudes from printed circuit 122, so that the surface of component 120 is flush with the surface of printed circuit 122 as shown in FIG. 17, or so that the surface of component 120 lies below that of printed circuit 122). Printed graphene traces such as traces 134-1 and 134-2 and embedded printed circuit traces such as metal traces 128 may be used to interconnect embedded components such as illustrative component 120 of FIG. 17 with each other and external circuitry. As shown in FIG. 17, for example, printed graphene trace 134-2 may couple one of component pads 126 with pad 130-1 on printed circuit 122 and printed graphene trace 134-1 may couple another one of component pads 126 with pad 130-2 and associated embedded traces 128 in printed circuit 122. A gap may separate component 120 from the surrounding walls of cavity 150. To ensure that printed graphene traces such as traces 134-1 and 134-2 are not disrupted by the gap between component 120 and the surrounding walls of cavity 150 in printed circuit 122, dielectric fill 152 (e.g., plastic such as epoxy or other thermoset plastic or a thermoplastic material) may be incorporated into the gap between printed circuit and component 120 as shown in FIG. 17. Gap-filling material 152 may serve as a bridge that helps support traces such as traces 134-1 and 134-2 as they run between contacts 126 and pads 130-1 and 130-2.

The foregoing is merely illustrative and various modifications can be made by those skilled in the art without departing from the scope and spirit of the described embodiments. The foregoing embodiments may be implemented individually or in any combination.

What is claimed is:

1. A connector, comprising:
a dielectric structure; and
connector contacts formed from printed graphene traces on the dielectric structure.

2. The connector defined in claim 1 wherein the connector contacts comprise metal pads on the printed graphene traces.

3. The connector defined in claim 2 further comprising solder that couples the metal pads to the printed graphene traces.

4. The connector defined in claim 2 wherein the metal pads comprise metal deposited directly on the printed graphene traces.

5. The connector defined in claim 1 wherein the dielectric structure comprises molded plastic.

6. The connector defined in claim 5 wherein the printed graphene traces comprises inkjet-printed graphene traces.

7. The connector defined in claim 5 wherein the molded plastic comprises a plastic structure with at least one right-angle bend and wherein a portion of the graphene traces overlaps the bend.

8. The connector defined in claim 7 wherein the bend has a radius of curvature of at least 0.01 mm.

9. The connector defined in claim 1 wherein the dielectric structure comprises a plastic member having an upper surface and an opposing lower surface and wherein the printed graphene traces include inkjet-printed graphene traces on the upper surface and inkj et-printed graphene traces on the lower surface.

10. The connector defined in claim 9 further comprising:
a support structure; and
an elastomeric member that couples the plastic member to the support structure.

11. The connector defined in claim 10 further comprising a metal shell in which the support structure is mounted.

12. The connector defined in claim 11 further comprising a ground formed from an inkjet-printed graphene trace that wraps around multiple surfaces of the plastic member.

13. Apparatus, comprising:
a printed circuit board having a metal trace;
an electrical component mounted to the printed circuit board; and
a graphene trace that covers at least part of the metal trace and that electrically couples the electrical component to the metal trace.

14. The apparatus defined in claim 13 further comprising plastic molded over at least a portion of the printed circuit board.

15. The apparatus defined in claim 14 wherein a portion of the graphene trace is formed on the plastic.

16. The apparatus defined in claim 15 wherein the printed circuit board has a recess and wherein the electrical component is mounted within the recess.

17. The apparatus defined in claim 16 further comprising dielectric material that fills a gap between the electrical component and the printed circuit board within the recess, wherein the graphene trace overlaps the dielectric material.

18. The apparatus defined in claim 17 wherein the electrical component comprises an integrated circuit with contacts and wherein the graphene trace overlaps at least one of the contacts.

19. A method, comprising:
molding a plastic material to form a plastic connector structure; and
inkjet printing graphene traces onto the plastic connector structure.

20. The method defined in claim 19 wherein the plastic connector structure has a surface with at least one right-angle bend, wherein inkjet printing the graphene traces comprises inkjet printing the graphene traces over the right-angle bend, and wherein inkjet printing the graphene traces further comprises printing connector contacts for an electrical connector that includes the plastic connector structure, the method further comprising:
mounting a plastic support in a metal connector shell for the electrical connector; and
attaching the plastic connector structure to the plastic support with an elastomeric member, wherein inkjet printing the graphene traces comprises inkjet printing the graphene traces to form connector contacts on the plastic connector structure and to form a signal path that extends along the plastic connector structure and the elastomeric member.
